(19) United States
(12) Patent Application Publication
(10) Pub. No.: US 2018/0364283 A1
(43) Pub. Date: Dec. 20, 2018

(54) SMARTPHONE-CONNECTABLE MULTIMETER HAVING AUTOMATIC MEASUREMENT TARGET DETECTION FUNCTION, AND MEASUREMENT SYSTEM INCLUDING THE SAME

(71) Applicant: Y TECH CO.,LTD., Gyeonggi-do (KR)

(72) Inventor: Yongman KIM, Seoul (KR)

(73) Assignee: Y TECH CO., LTD., Gyeonggi-do (KR)

(21) Appl. No.: 16/060,210

(22) PCT Filed: Sep. 30, 2016
(86) PCT No.: PCT/KR2016/011020

§ 371 Date: Jun. 7, 2018

(30) Foreign Application Priority Data
Sep. 30, 2016 (KR) 10-2016-0126200

(51) Int. Cl. G01R 15/12; G01R 1/04; G01R 1/073; G01R 31/28; H04M 1/02

(52) U.S. Cl. CPC G01R 15/125; G01R 1/04; H04M 1/0274; G01R 31/2886; G01R 1/073

(57) ABSTRACT

A smartphone-connectable multimeter having an automatic measurement target detection function, a measurement system including the same, and a measurement method using the same is provided. The smartphone-connectable multimeter includes: a housing; a pair of lead wires equipped with probes, and drawn from the housing; a range module configured to rectify and transform an electric signal, and installed in the housing; a voltage module configured to generate electricity and apply current to the measurement target; and a process module configured to receive instruction data, to generate analysis data by converting the electric signal, processed by the range module, into a corresponding digital signal suitable for an electrical characteristic according to settings of the instruction data and analyzing the digital signal, and to perform control so that the voltage module applies current when an electric signal is not received from the measurement target, and installed in the housing.

### BACKGROUND

The present invention relates to a smartphone-connectable multimeter having an automatic measurement target detection function, by which a user can easily measure a desired electrical characteristic of a measurement target without performing an input procedure, such as the selection of measurement details, a measurement target, and/or the like, in advance in order to perform the measurement of the measurement target, a person unskilled in a related technical field can easily measure electrical characteristics of various types of measurement targets, and carrying and storage are facilitated and thus the storage and utilization properties of the multimeter are improved, and also relates to a measurement system including the same and a measurement method using the same.

As is known well, a multimeter is an electrical measuring device in which various measuring functions, i.e., a function of measuring the electricity resistance of a conductor, a function of measuring voltage between two points, a function of measuring current, etc., are combined together. Such multimeters are widely used at various industrial sites.

Meanwhile, a conventional multimeter, particularly a digital multimeter, is fabricated by integrating lead wires configured to come into contact with target points and then collect an electric signal in order to measure electricity and output the results of the measurement, a range configured to transform and adjust the collected electric signal into designated form, a processor configured to analyze the adjusted electric signal and convert the results of the analysis into data, and a display configured to output the data in text or image form. Accordingly, the conventional multimeter is a portable single device having a relatively large size.

However, an operator must carry a number of devices as well as a multimeter at an industrial site, and thus it is preferable to reduce the number of devices which are carried by an operator.

Meanwhile, ordinary persons who do not use a multimeter frequently do not feel the need to have a multimeter, and thus ordinary persons rarely have multimeters having a relatively large size in their homes. However, as domestic electrical products become more diversified and the number thereof increases, there are increasing cases in which ordinary persons need to check electrical products for their states in case of emergency, and thus ordinary persons start to feel the need for a multimeter.

The conventional multimeter is a single device having a relatively large size, as described above. Accordingly, in spite of the above-described need, ordinary persons accept inconvenience without furnishing their homes with multimeters.

In order to overcome the above problem, there has been proposed a conventional technology for combining a multimeter with a smartphone, which is a necessity which is always carried by an operator or ordinary person (hereinafter referred to as a “user”). This technology includes only lead wires, a range, and a processor which perform a function in which a multimeter connected to a smartphone collects and measures an electric signal of a measurement target and converts the electric signal into data. The smartphone performs a display function of simply outputting data transferred from the multimeter. Accordingly, the conventional multimeter has a low cost, and is operated in conjunction with a smartphone familiar with a user, thereby improving convenience compared to an independent conventional multimeter.

However, the conventional multimeter technology is configured such that the smartphone simply performs only a monitor function, and thus a user connected to the smartphone suffers from inconvenience in that he or she must directly manipulate the multimeter. For this purpose, a problem arises in that the conventional multimeter must have a sufficiently large size. It will be apparent that this inconvenience results in the reluctance of users to the use of multimeters, and thus the problem of the conventional multimeter is not overcome.

### SUMMARY OF THE INVENTION

The present invention has been conceived to overcome the above-described problems, and an object of the present invention is to provide a smartphone-connectable multimeter having an automatic measurement target detection function, by which an ordinary unskilled person can easily measure an electrical characteristic of a measurement target, a user can determine measurement information regarding a measurement target without inputting information in advance in order to perform measurement, and carrying and storage are facilitated and thus the storage and utilization properties of the multimeter are improved, and to also provide a measurement system including the same and a measurement method using the same.

According to an aspect of the present invention, there is provided a smartphone-connectable multimeter having an automatic measurement target detection function, including:

a housing;

a pair of lead wires equipped, at ends thereof, with probes adapted to come into contact with a measurement target, and drawn from the housing;

a range module configured to rectify and transform an electric signal received by the lead wires, and installed in the housing;

a voltage module configured to generate electricity of a designated voltage and apply current to the measurement target; and

a process module configured to receive instruction data while communicating with a program module of a smartphone, to generate analysis data by converting the electric signal, processed by the range module, into a corresponding digital signal suitable for an electrical characteristic according to settings of the instruction data and analyzing the digital signal, and to perform control so that the voltage module applies current when an electric signal is not received from the measurement target, and installed in the housing.

According to another aspect of the present invention, there is provided a measurement system, including:

a smartphone-connectable multimeter configured to include: a housing; a pair of lead wires equipped, at ends thereof, with probes adapted to come into contact with a measurement target, and drawn from the housing; a range module configured to rectify and transform an electric signal received by the lead wires, and installed in the housing; a voltage module configured to generate electricity of a designated voltage and apply current to the measurement target; and a process module configured to receive instruction data while communicating with a program module of a smartphone, to generate analysis data by converting the electric signal, processed by the range module, into a corresponding digital signal suitable for an electrical characteristic according to settings of the instruction data and analyzing the digital signal, and to perform control so that the voltage module applies current when an electric signal is not received from the measurement target, and installed in the housing; and

a program module configured to generate instruction data for control of the multimeter in accordance with input of a user or its own process and send the instruction data to the multimeter and to examine the analysis data and output measurement details regarding the electrical characteristic of the measurement target via an input and output module of the smartphone, and installed in the smartphone so that the program module operates in conjunction with an operating system (OS) of the smartphone.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a diagram schematically showing a state in which a multimeter according to the present invention is connected to a smartphone;

FIG. 2 is a block diagram showing the configuration of a measurement system according to the present invention;

FIG. 3 is a flowchart sequentially showing a measurement method using a multimeter according to an embodiment of the present invention;

FIG. 4 is a diagram showing measurement using a multimeter according to the present invention;

FIG. 5 is a diagram showing an operational embodiment of a multimeter according to the present invention;

FIG. 6 is a view schematically showing the cooperative operation of a multimeter and a smartphone according to the present invention;

FIG. 7 is a flowchart sequentially showing a measurement method using a multimeter according to another embodiment of the present invention;

FIG. 8 is a view showing the input of product information regarding a measurement target to a smartphone according to the present invention; and

FIG. 9 is a view showing the loading of guide data based on the cooperative operation of a smartphone and a multimeter according to the present invention.

### DETAILED DESCRIPTION OF THE INVENTION

Embodiments of the present invention will be described in detail below with reference to the accompanying drawings.

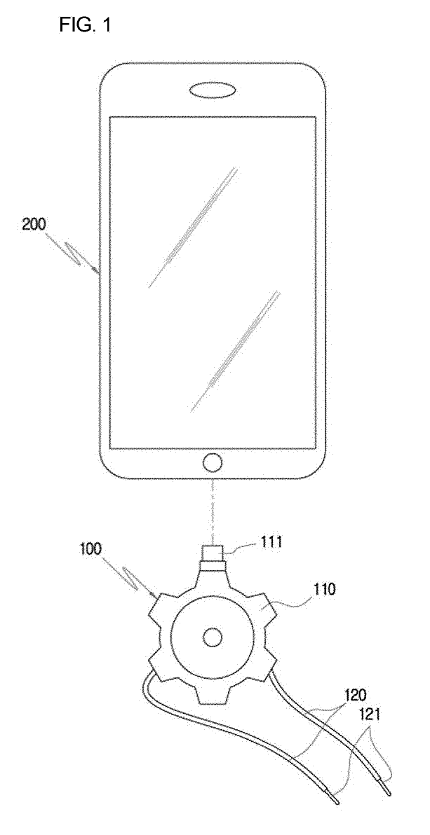

FIG. 1 is a diagram schematically showing a state in which a multimeter 100 according to an embodiment of the present invention is connected to a smartphone 200.

The multimeter 100 according to the present embodiment is connected to the smartphone 200 via a small-sized USB port, an earphone port, or the like (hereinafter referred to as the “port”) formed in the smartphone 200. For this purpose, the multimeter 100 includes a small-sized USB plug or earphone jack (hereinafter referred to as the “code 111”) in the housing 110 thereof.

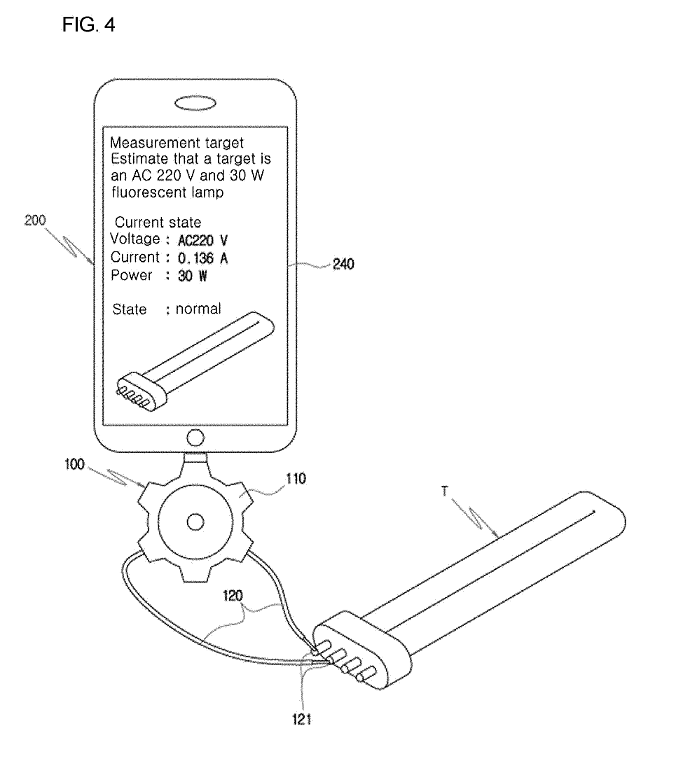

Furthermore, the multimeter 100 according to the present embodiment measurement target T includes a pair of lead wires 120 configured to be connected to specific points and drawn from the housing 110 in order to detect an electric signal of a measurement target (T; see FIG. 4), which is an electrical outlet, a lamp, a coil, or one of various types of electrical products. For this purpose, a pair of probes 121 configured to come into contact with specific points of the measurement target T are formed at ends of the lead wires 120. Since the configuration and structure of the lead wires 120 are well known, detailed descriptions of the inner wires, shapes and structure of the lead wires 120 are omitted.

Meanwhile, the multimeter 100 according to the present embodiment does not include a separate mechanical control panel and a separate monitor, and thus the housing 110 of the multimeter 100 is preferably formed in a size and shape which can be conveniently carried and easily stored.

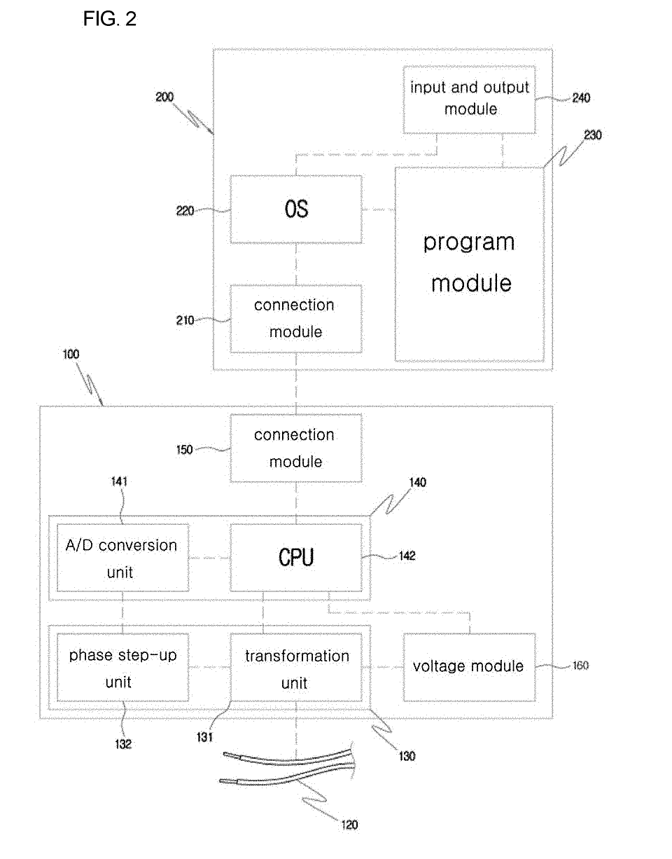

FIG. 2 is a block diagram showing the configuration of a measurement system according to an embodiment of the present invention.

The multimeter 100 according to the present embodiment will be described in greater detail with reference to FIG. 2.

The multimeter 100 according to the present embodiment includes: a range module 130 configured to adjust an electric signal received by the lead wires 120; and a process module 140 configured to generate analysis data, in which a corresponding electrical characteristic is recorded, by analyzing the adjusted electric signal, to send the analysis data, and to operate in compliance with instruction data received from the smartphone 200.

Furthermore, the multimeter 100 according to the present embodiment includes a connection module 150 configured to perform connection in order to communicate with the smartphone 200. In the present embodiment, an end of the connection module 150 of the multimeter 100 is connected to the plug 111. Accordingly, the connection module 150 sends and receives communication signals between the multimeter 100 and the smartphone 200 via the plug 111. For reference, the connection module 150 includes a wiring structure between the process module 140 and the plug 111, and may include a serial converter configured to adjust the type of communication. Meanwhile, the wiring structure of the connection module 150 may vary depending on the type of plug 111 (an earphone jack, a small-sized USB plug, or the like) and/or the type of communication. For reference, although communication between the smartphone 200 and the multimeter 100 via the connection module 150 is performed in a wired manner in the present embodiment, a short distance wireless communication technology, such as Bluetooth, may be applied.

A program module 230 installed on the smartphone 200 receives analysis data from the multimeter 100, processes the analysis data, includes measurement details, obtained through the processing of the analysis data, in measurement information, outputs the measurement information via an input and output module 240, generates corresponding instruction data in accordance with an input of a user or its own process, and sends the instruction data to the multimeter 100.

The program module 230 is an application programmed to be executed based on the OS 220 of the smartphone 200. The program module 230 according to the present embodiment utilizes the connection module 210 and the input and output module 240, included in the smartphone 200, by means of the OS 220, like well-known applications. For reference, the program module 230 may post a plurality of menu options on the output screen of the smartphone 200, and may generate instruction data adapted to set various types of commands, analysis conditions, analysis environments, or the like in order to output corresponding analysis data when a user selects one from among the menu options output onto a page of the smartphone 200. Next, the program module 230 performs processing such that the measurement details according to the corresponding menu are posted on the input and output module 240 of the smartphone 200 in compliance with the generated instruction data. Furthermore, the program module 230 may send the instruction data to the multimeter 100 so that the multimeter 100 analyzes the analysis data in accordance with the settings and send the result of the analysis. For reference, the multimeter 100 may analyze all electrical characteristics of the measurement target T and send corresponding analysis data to the program module 230, and the program module 230 may output only corresponding measurement details in accordance with a set mode. However, furthermore, the multimeter 100 may generate and send only designated analysis data in compliance with instruction data received from the program module 230.

The individual components and operation process of the above-described multimeter 100 according to the present invention will be described in greater detail in conjunction with the following measurement method.

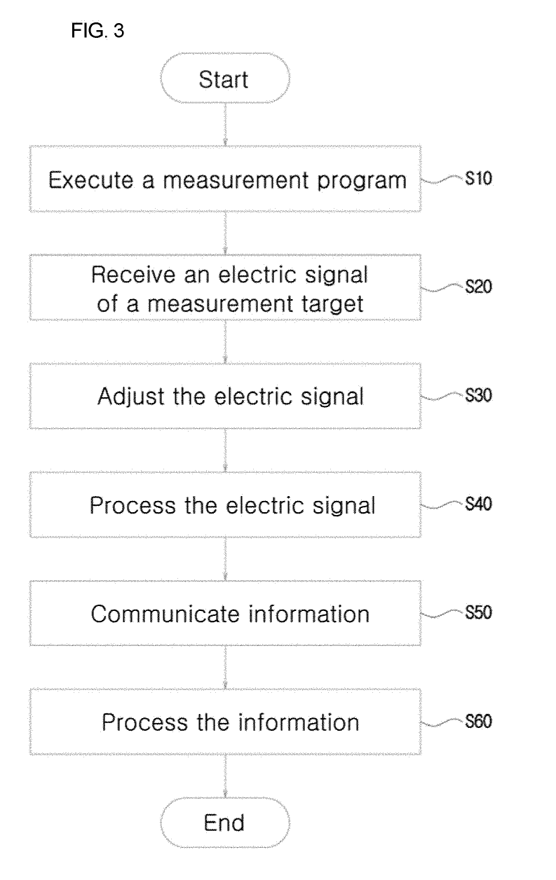

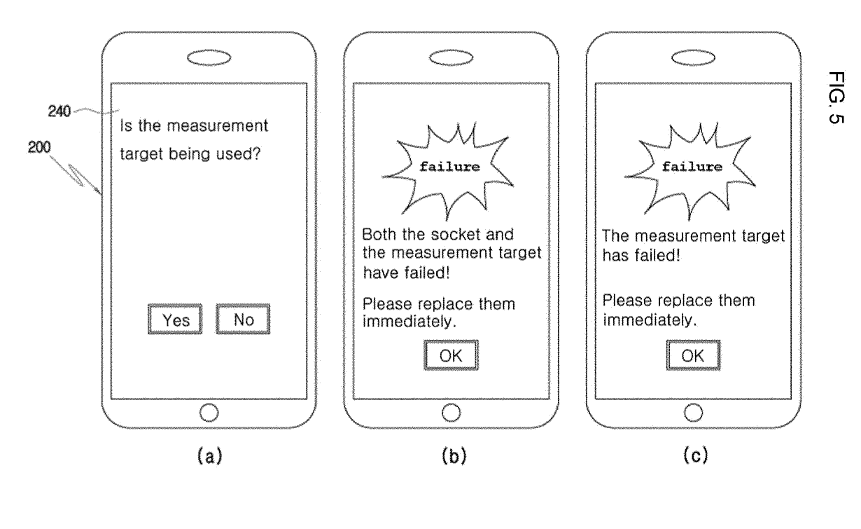

FIG. 3 is a flowchart sequentially showing a measurement method using a multimeter according to an embodiment of the present invention, FIG. 4 is a diagram showing measurement using a multimeter according to the present invention, and FIG. 5 is a diagram showing an operational embodiment of a multimeter according to the present invention.

S10: Measurement Program Execution Step

As is well known, an application installed on the smartphone 200 is executed based on the OS 220. The application generates an icon on the screen of the smartphone 200. When a user clicks on the icon, the corresponding application outputs a main page while being executed. The user selects a menu option for measurement while viewing the main page. Menu options according to the present embodiment may include various options, such as “electrical product measurement without selection”, “selected electrical product measurement”, “measurement method guide,” etc. In the present embodiment, “electrical product measurement without selection,” which is an option by which a user immediately starts measurement without selecting an electrical product, is used. In other words, even when a user does not input anything, such as information about a measurement target, details to be measured, or the like, the multimeter according to the present embodiment collects measurement details from the measurement target T and outputs the measurement details as measurement information via the smartphone 200. Even a user unskilled in the measurement of an electrical product can easily obtain required measurement information.

For reference, although selective menu options are output to a user when the user executes the application installed on the smartphone 200 in the present embodiment, only the guide announcement “bring probes into contact with a corresponding location of a measurement target” or the like may be simply output when the user executes the application.

When a user selects the menu option “selected electrical product measurement,” other than the menu option according to the present embodiment, a window for the input of information about a measurement target may be output, and measurement details to be measured may be input. When a user designates measurement details, the program module 230 sends instruction data for the mode setting of the multimeter 100 to the multimeter 100 in order to generate the analysis data of the corresponding measurement details.

S20: Measurement Target Electric Signal Reception Step

The pair of probes 121 famed at ends of the lead wires 120 according to the present embodiment are brought into contact with the terminal portions of the measurement target T. When the specific points of the measurement target T do not conduct electricity, the probes 121 of the lead wires 120 neither receive an electric signal nor transfer an electric signal to the range module 130. However, when the specific points conduct electricity, the probes 121 of the lead wires 120 receive a corresponding electric signal, and the electric signal received as described above is transferred to the range module 130.

For reference, when the measurement target T has been currently connected to a power source (hereinafter referred to as the “socket”), such as a normal socket (not shown), a capacitor, or the like and is being operated, this means that current is applied to the measurement target T by a separate external voltage, and thus an electric signal is received via the probes 121 in contact with the measurement target T. In contrast, when the measurement target T has been separated from the socket, the socket itself has a problem, or both the socket and the measurement target have problems, the probes 121 in contact with the measurement target T do not receive an electric signal. When the measurement target T receives voltage of a designated or higher magnitude, it may be determined that the measurement target T has failed or the probes 121 are brought into contact with wrong terminal locations.

Next, when an electric signal is not received, the multimeter 100 according to the present embodiment may prompt a user to check the measurement target T or socket or may apply current to the measurement target T in order to determine whether the measurement target T or socket has failed. This is discussed in greater detail in terms of configuration. That is, a voltage module 160 installed inside the multimeter 100 determines whether an electric signal is received by the probes 121 in contact with the measurement target T by generating voltage of designated magnitude and then applying the voltage to the measurement target T under the control of the CPU 142.

When the current of the voltage module 160 is applied, the normal measurement target T transfers a corresponding electric signal to the probes 121 through operation. Thereafter, when the probe 121 receives a normal electric signal, the multimeter 100 performs the measurement of the measurement target T based on the normal electric signal. Meanwhile, when an electric signal is not received by the probes 121 after the current application of the voltage module 160, it may be estimated that the measurement target T has a problem or both the measurement target T and the socket have problems. For reference, when the program module 230 according to the present embodiment does not receive measurement details regarding the measurement target T via analysis data received after the current application from the multimeter 100, the program module 230 inquires the state of the measurement target T or the like from a user, as shown in FIG. 5(a), and performs output when the user selects “Yes,” as shown in FIG. 5(b).” In contrast, when the user selects “No,” the program module 230 performs output, as shown in FIG. 5(c). For reference, since the fact that the user selects “Yes” means that the measurement target T has been connected to the socket and the fact that an electric signal is not received even when the voltage module 160 has applied current means that neither the measurement target T nor the socket normally conduct electricity, the program module 230 according to the present embodiment performs output, as shown in FIG. 5(b). In contrast, since the fact that the user selects “No” means that the measurement target T has not been connected to the socket and the fact that an electric signal is not received even when the voltage module 160 has applied current means that the measurement target T does not normally conduct electricity, the program module 230 according to the present embodiment performs output, as shown in FIG. 5(c).

Meanwhile, although the voltage module 160 included in the multimeter 100 may be the multimeter 100's own battery, it is preferably configured to receive power from the smartphone 200 and apply power to the measurement target T.

S30: Electric Signal Adjustment Step

The range module 130 which has received the electric signal adjusts the electric signal in accordance with a condition for the allowance of the processing of the process module 140. For this purpose, the range module 130 includes: a voltage transformation unit 131 configured to transform the voltage of the electric signal in accordance with a condition for the allowance of the processing of the process module 140; and a phase step-up unit 132 configured to convert the phase of the received electric signal into a sine wave having only (+) components. The range of voltages which can be received and analyzed by the process module 140 is limited, whereas the multimeter 100 can receive electric signals of various voltages. Accordingly, the range module 130 includes a voltage transformation unit 131 configured to convert electric signals of various voltages, received from the outside, into the range of voltages of the analysis of the process module 140. Although the voltage transformation unit 132 according to the present embodiment may be limited to only a step-down function because measurement is chiefly performed in connection with high voltages of AC 110 V and AC 220 V, the voltage transformation unit 132 may be equipped with a step-up function for a case where measurement is performed by applying minute current by itself, as described above. As a result, the voltage transformation unit 131 selectively performs a step-down and a step-up function under the control of the CPU 142 according to the electric signal.

Meanwhile, the multimeter 100 according to the present embodiment can perform measurement regarding measurement targets T related to DC electricity and AC electricity. Accordingly, when the electric signal is DC electricity, the phase step-up unit 132 maintains the electric signal. In contrast, when the electric signal is AC electricity, the phase step-up unit 132 converts the electric signal into a sine wave. For example, when an electric signal of AC 220 V is input, the electric signal is stepped down to AC 2.2 V at a ratio of 1/100 via the voltage transformation unit 131. In this case, AC changes from +2.2 V to −2.2 V 60 times. A reference point of 0 V is increased to +2.3 V, and a sine wave changing within a range of +0.1 V to +4.5 V and having only (+) components is obtained.

As a result, the range module 130 rectifies and transforms the electric signal received from the measurement target T, and transfers the resulting signal to the process module 140.

S40: Electric Signal Processing Step

The process module 140 analyzes the electric signal received from the range module 130, and outputs analysis data regarding the electrical characteristic of the electric signal, such as the voltage, current, resistance, wave or the like of the electric signal. Furthermore, the process module 140 sets the type of characteristic of the electric signal to be measured by the multimeter 100, a measurement condition, etc. by processing instruction data received from the smartphone 200. For this purpose, the process module 140 includes: an A/D conversion unit 141 configured to convert the electric signal, received from the range module 130, into digital form; and a CPU 142 configured to analyze the digital-type electric signal, to output analysis data, and to receive and process the instruction data.

Since the electric signal adjusted by the range module 130 is in analog form, the process module 140 which processes a signal in digital form cannot process the electric signal received from the range module 130. Accordingly, the A/D conversion unit 141 of the process module 140 converts the electric signal, adjusted by the range module 130, into digital form.

The CPU 142 analyzes the electric signal in digital form according to a set process, outputs analysis data regarding the electrical characteristic of the electric signal, and sets a processing environment so that the instruction data received from the smartphone 200 is processed and analysis data suitable for the instruction data is output. Furthermore, even in the case where separate instruction data is not received from the smartphone 200, when there is not voltage during the analysis of the electric signal, a corresponding electric signal may be received by applying a current of required voltage through the control of the voltage module 160.

Accordingly, when the instruction data is a signal instructing that the measurement target T is checked only for current, the CPU 142 analyzes only the current of the electric signal in digital form, and outputs the result of the analysis. Furthermore, when the instruction data is a signal instructing that the measurement target T is checked only for voltage, the CPU 142 analyzes only the voltage of the electric signal in digital form, and outputs the result of the analysis. Alternatively, regardless of the instruction data, the CPU 142 may output analysis data obtained by analyzing various electrical characteristics, and may send all the analysis data to the smartphone 200. Alternatively, the CPU 142 may analyze all electrical characteristics, may output the results of the analysis, may select only analysis data corresponding to the instruction data, and may send the corresponding analysis data to the smartphone 200. Furthermore, the instruction data may be a signal instructing that ON/OFF of the multimeter 100 is controlled.

For reference, the analysis data generated by the CPU 142 may be data regarding an electrical characteristic, such as voltage, current, resistance, power, wave, or the like, of the measurement target T. At least one of voltage, current, resistance, power, wave, and the like may be obtained by computing another electric signal, and the data obtained through the computation may be generated as analysis data.

S50: Information Communication Step

The process module 140 of the multimeter 100 transfers the analysis data to the smartphone 200. Furthermore, the process module 140 receives the instruction data from the smartphone 200. This information communication is performed via the connection module 150 of the multimeter 100 and the connection module 210 of the smartphone 200.

For reference, the connection module 210 of the smartphone 200 includes: a port configured such that the plug 111 of the multimeter 100 is mechanically engaged therewith; and a wiring structure configured to extend from the OS 220 to the program module 230. Since the connection module 210 of the smartphone 200 corresponds to a well-known technology, a detailed description thereof is omitted.

S60: Information Processing Step

The analysis data received from the multimeter 100 is processed by the program module 230, and is then output onto the input and output module 240 of the smartphone 200 in designated format, as shown in FIG. 4.

As described above, the program module 230 is an application programmed to be executed based on the OS 220 of the smartphone 200. The program module 230 outputs page onto the input and output module 240 of the smartphone 200 in designated format, and posts measurement details, i.e., an electrical characteristic of the measurement target T, at a corresponding location of the page as measurement information. In other words, the program module 230 converts the measurement details into measurement information in format, such as a numeral, a graph, text, or the like, and posts the measurement information.

As described above, the program module 230 according to the present embodiment is executed in response to clicking on a corresponding icon, and outputs a page onto the input and output module 240 in designated format. Furthermore, when a user selects a menu option of the page, the program module 230 generates instruction data corresponding to the corresponding menu option, and sends the instruction data to the multimeter 100. Furthermore, the program module 230 processes the analysis data received from the multimeter 100, and posts corresponding measurement details on designated items of a page.

The program module 230 according to the present embodiment processes the analysis data received from the multimeter 100, and determines one or more selected from among electrical characteristics, such as current, voltage, resistance, wave, and the like, of the measurement target T. When only one of the electrical characteristics is determined, the program module 230 may output only this information. When two or more measurement details of the electrical characteristics are determined, the program module 230 may determine one or more other measurement details by computing the two or more measurement details. Moreover, the program module 230 may determine the wave state of the electrical characteristics, may determine a rule and a feature, and may collect them as information.

Next, the program module 230 may search for a corresponding electrical product by comparing the determined measurement details with information about electrical products stored in its own data unit (not shown).

In greater detail, the data unit stores information about various types of electrical products, etc. The information about various types of electrical products may include images of the electrical products, the names of the electrical products, the electrical specifications, such as current, voltage, resistance, power, etc., of the electrical products. The program module 230 searches for electrical product information corresponding to measurement details, obtained by processing the analysis data, by comparing the measurement details with the information about electrical products stored in the data unit.

When, as a result of the search, the electrical product information corresponding to the measurement details has been retrieved, the program module 230 outputs the type and details of the electrical product information via the input and output module 240 of the smartphone 200. As an example, when the type of measurement target T corresponds to one selected from among electrical products, including a capacitor, a coil, a light bulb, a fluorescent lamp, etc., the program module 230 may determine it, and may output the corresponding type of electrical product to the input and output module 240. When detailed electrical product information regarding the corresponding measurement target T is present, the specific details of the electrical product information may be output along with an image thereof, as shown in FIG. 4.

For reference, although the output via the input and output module 240 may be generally performed via a screen, measurement details may be output in sound form via the speaker of the smartphone 200.

When the electrical product information output to the smartphone 200 is identical or similar to information about the current measurement target T, the reliability of the determined measurement details and search details can be increased, and also information about the corresponding measurement target T can be additionally obtained.

When there is no corresponding electrical product information, the program module 230 outputs only measurement information regarding the measurement details via the input and output module 240, and a user may examine a final measurement result while viewing the output measurement details. Moreover, the program module 230 may determine whether the measurement target T has failed, and may output the result of the determination through cooperative operation with the process module 140 of the multimeter 100, as shown in FIG. 5.

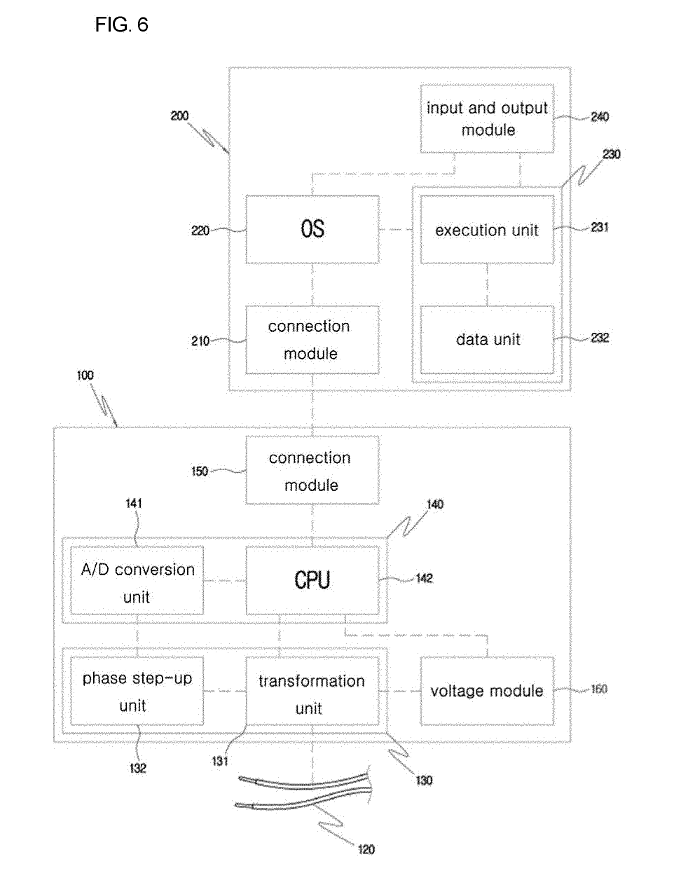

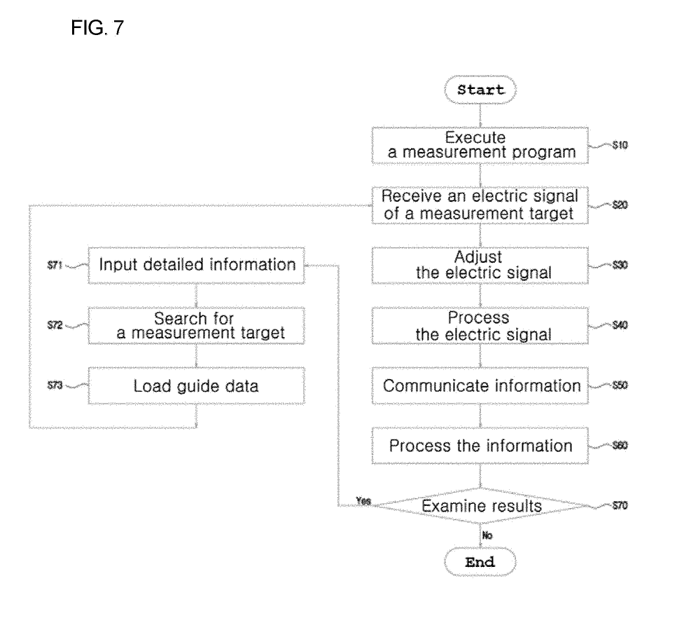

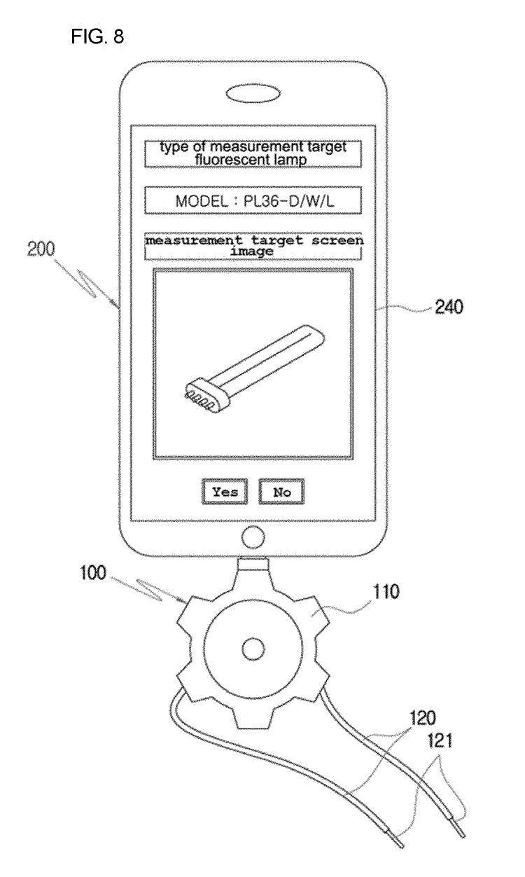

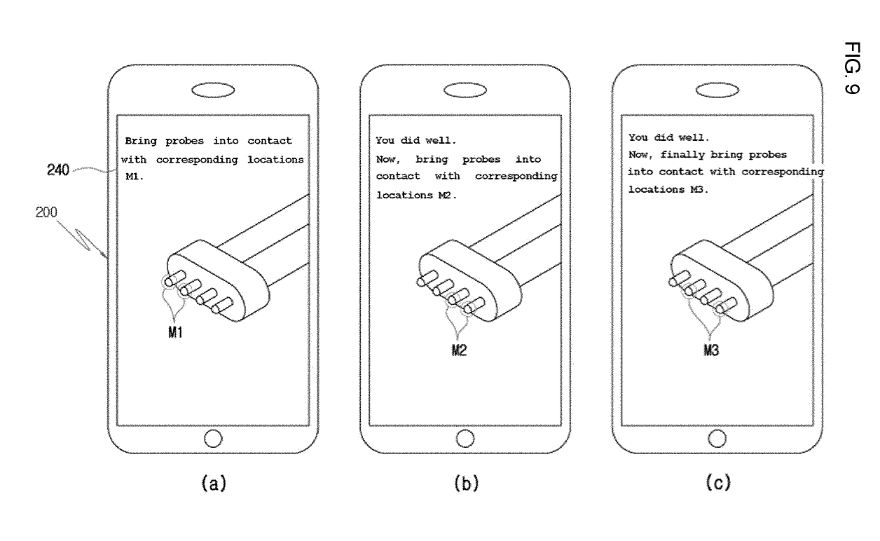

FIG. 6 is a view schematically showing the cooperative operation of a multimeter and a smartphone according to the present invention, FIG. 7 is a flowchart sequentially showing a measurement method using a multimeter according to another embodiment of the present invention, FIG. 8 is a view showing the input of product information regarding a measurement target to a smartphone according to the present invention, and FIG. 9 is a view showing the loading of guide data based on the cooperative operation of a smartphone and a multimeter according to the present invention.

S70: Result Examination Step

The program module 230 prompts the user to examine the measurement information, such as measurement details and search details, output to the smartphone 200 at information processing step S60. Although, as a result of the examination, the user may be satisfied with the measurement information output to the smartphone 200, there may be a difference between the measurement target T and the measurement information, or desired details may not be present in the measurement details.

In order to prepare for this case, the program module 230 inquires whether the user is satisfied with the measurement information from the user, and terminates the corresponding measurement when the user expresses satisfaction.

S71: Detailed Information Input Step

In contrast, when the user is not satisfied with the measurement information, the program module 230 requests detailed information regarding the corresponding measurement target T in order to perform more detailed measurement and search, as shown in FIG. 8, and the user identifies information about the measurement target T and inputs the detailed information to corresponding spaces.

At “measurement detail setting step S10” of the measurement method according to the present invention, a user unskilled in measurement may be guided through a procedure for the measurement of a specific measurement target T.

The program module 230 according to the present embodiment includes: an execution unit 231 configured to determine analysis data and output corresponding measurement details as measurement information, as described above, and to generate corresponding instruction data in compliance with measurement details selected by the user; and a data unit 232 configured to store guide data about a procedure for the measurement of the measurement target T together with electrical product information regarding the measurement target T. In this case, the data unit 232 may store guide data about a procedure for the measurement of a corresponding electric signal with respect to a measurement target, such as an electrical product which can be easily encountered around the user. The output of the guide data may be performed in the form of a file of a moving image, subtitles, images, sounds, and/or the like. For reference, the program module 230 executes guide data by means of the input and output module 240 of the smartphone 200.

Next, the execution unit 231 of the program module 230 outputs an input page, adapted to enable the user to directly input measurement target T-related information for the guidance of measurement, and a selection page, adapted to list related types of electrical product information based on measurement information determined in advance through measurement, to the input and output module 240 of the smartphone 200. In the case of an input page, the user may directly input information about the measurement target T to input spaces shown in FIG. 8. Furthermore, the program module 230 may receive simple information about the measurement target T, such as the type and model name of the measurement target T, and may output corresponding various names in the form of the list of the selection page based on the received information.

S72: Measurement Target Search Step

The program module 230 searches the data unit based on the detailed information input by the user, and outputs an electrical product image as the result of the search, as shown in FIG. 8.

The user examines the electrical product image, and finally determines a desired measurement target T.

S73: Guide Data Loading Step

Once the electrical product regarding the measurement target T has been determined, the execution unit 231 searches for guide data about the electrical product in the data unit 232, loads the retrieved guide data, and outputs guide messages via the input and output module 240, as shown in FIG. 9.

Although the guide messages are illustrated as guide announcements and images in the present embodiment, only moving images or simple sounds may be output.

In general, although the measurement of the measurement target T may be performed in such a way that the probes 121 are brought into contact with specific portions once, there may be a case where the probes 121 need to be brought into contact with various locations a plurality of times. In this case, the guide messages sequentially guide the user through the procedure so that the user can follow the guidance. In this case, as shown in FIG. 9, the user brings the probes 121 into contact with terminals in a sequence indicated by the guide messages, and subsequent guide messages regarding a subsequent procedure are output when it is determined that an electric signal has been input, thereby allowing the subsequent procedure to be performed.

Although the provision of guide messages and the performance of measurement are performed at the same time in the present embodiment, only guide data about an overall measurement procedure may be loaded first before the actual measurement of the measurement target T, and the user does not start the measurement of the measurement target T until the execution of the guide data about a measurement procedure is completed.

Although the above-described steps S71 to S73 are performed after whether the user is satisfied with measurement has been determined after the measurement of the measurement target T, the menu option “select electrical product measurement” or “measurement method guidance” may be immediately performed when the user selects the menu option at measurement program execution step S10.

According to the present invention, advantages arise in that an ordinary unskilled person can easily measure an electrical characteristic of a measurement target, a user can determine measurement information regarding a measurement target without inputting information in advance in order to perform measurement, and carrying and storage are facilitated and thus the storage and utilization properties of the multimeter are improved.

Furthermore, although the range of the conventional multimeter performs corresponding measurement only if a user directly and accurately selects measurement details regarding an electrical characteristic, such as voltage, current, electricity type (AC/DC), a disconnection, resistance, or the like, of a measurement target, the present invention can automatically detect measurement details regarding a measurement target and display the measurement details on a smartphone (examples of display on a screen: AC 220 V, DC 12 V, DC 1.43 V, disconnected, connected, 35 Kohm, etc.). Accordingly, an advantage arises in that a user can obtain desired measurement information on a smartphone only by bringing the leads of the multimeter into contact with a measurement target, through which an ordinary unskilled person can easily measure electrical characteristics of various types of measurement targets without particular difficulty.

Although the specific embodiments of the present invention have been disclosed for illustrative purposes, those skilled in the art will appreciate that various modifications, additions and substitutions are possible without departing from the scope and spirit of the invention as disclosed in the accompanying claims.

1. A smartphone-connectable multimeter having an automatic measurement target detection function, comprising:
a housing;
a pair of lead wires equipped, at ends thereof, with probes adapted to come into contact with a measurement target, and drawn from the housing;
a range module configured to rectify and transform an electric signal received by the lead wires, and installed in the housing;
a voltage module configured to generate electricity of a designated voltage and apply current to the measurement target; and
a process module configured to receive instruction data while communicating with a program module of a smartphone, to generate analysis data by converting the electric signal, processed by the range module, into a corresponding digital signal suitable for an electrical characteristic according to settings of the instruction data and analyzing the digital signal, and to perform control so that the voltage module applies current when an electric signal is not received from the measurement target, and installed in the housing.

2. The smartphone-connectable multimeter of claim 1, wherein the voltage module generates voltage by processing power received from the smartphone.

3. A measurement system, comprising:
a smartphone-connectable multimeter configured to comprise: a housing; a pair of lead wires equipped, at ends thereof, with probes adapted to come into contact with a measurement target, and drawn from the housing; a range module configured to rectify and transform an electric signal received by the lead wires, and installed in the housing; a voltage module configured to generate electricity of a designated voltage and apply current to the measurement target; and a process module configured to receive instruction data while communicating with a program module of a smartphone, to generate analysis data by converting the electric signal, processed by the range module, into a corresponding digital signal suitable for an electrical characteristic according to settings of the instruction data and analyzing the digital signal, and to perform control so that the voltage module applies current when an electric signal is not received from the measurement target, and installed in the housing; and
a program module configured to generate instruction data for control of the multimeter in accordance with input of a user or its own process and send the instruction data to the multimeter and to examine the analysis data and output measurement details regarding the electrical characteristic of the measurement target via an input and output module of the smartphone, and installed in the smartphone so that the program module operates in conjunction with an operating system (OS) of the smartphone.

4. The measurement system of claim 3, wherein the program module comprises:
a data unit configured to store electrical product information including electrical characteristics and electrical product image for each electrical product; and
an execution unit configured to examine the analysis data and output corresponding measurement details to the input and output module as measurement information, and to search for corresponding electrical product information by comparing measurement details of the analysis data with the electrical characteristics stored in the data unit and output the retrieved electrical product information, together with the measurement information, to the input and output module.

5. The measurement system of claim 3, wherein the program module:
when measurement details regarding the measurement target are not present in analysis data received after current has been applied to the measurement target by the multimeter, inquires whether the measurement target is being used through connection with a power source, determines whether the measurement target and an adjacent electrical product connected to the measurement target have failed based on a result of the inquiry, and outputs a result of the determination to the input and output module.

6. The measurement system of claim 4, wherein the program module:
when measurement details regarding the measurement target are not present in analysis data received after current has been applied to the measurement target by the multimeter, inquires whether the measurement target is being used through connection with a power source, determines whether the measurement target and an adjacent electrical product connected to the measurement target have failed based on a result of the inquiry, and outputs a result of the determination to the input and output module.
The measurement system of claim 3, wherein the program module:
when measurement details regarding the measurement target are not present in analysis data received after current has been applied to the measurement target by the multimeter, inquires whether the measurement target is being used through connection with a power source, determines whether the measurement target and an adjacent electrical product connected to the measurement target have failed based on a result of the inquiry, and outputs a result of the determination to the input and output module.
